(19) United States
(12) Patent Application Publication
(10) Pub. No.: US 2004/0225944 A1
(43) Pub. Date: Nov. 11, 2004

(54) Systems and methods for processing an error correction code word for storage in memory components

(76) Inventor: Christopher M. Brueggen, Dallas, TX (US)

Correspondence Address: HEWLETT-PACKARD COMPANY, Intellectual Property Administration, P.O. Box 272400, Fort Collins, CO, 80527-2400, US

(21) Appl. No.: 10/435,150

(22) Filed: May 9, 2003

(51) Int. Cl. G11B 5/00; G06K 5/04; G11B 20/20; H03M 13/00

(52) U.S. Cl. 714/758

(57) ABSTRACT

In an embodiment, cache lines may be stored in memory by a memory controller. The memory controller formats cache lines into a plurality of portions for storage in the plurality of memory components, implements an error correction code (ECC) to correct a single-byte error in an ECC code word for pairs of the plurality of portions, stores even nibbles of respective pairs of the plurality of portions during respective first bus cycles, and stores odd nibbles of the respective pairs of plurality of portions during respective second bus cycles such that each byte of the respective pairs of the plurality of portions is stored in a single one of the plurality of memory components.

### RELATED APPLICATION

This application is related to concurrently filed and commonly assigned U.S. patent application Ser. No. ______, ATTORNEY DOCKET NO. 200300007-1, entitled “SYSTEMS AND METHODS FOR TESTING ERROR CORRECTION CODE FUNCTIONALITY IN A MEMORY SYSTEM,” which is incorporated herein by reference.

### FIELD OF THE INVENTION

The present invention is generally related to utilizing an error correction code (ECC) to store data in a memory system.

### DESCRIPTION OF RELATED ART

Electronic data storage utilizing commonly available memories (such as dynamic random access memory (DRAM)) can be problematic. Specifically, there is a probability that, when data is stored in memory and subsequently retrieved, the retrieved data will suffer some corruption. For example, DRAM stores information in relatively small capacitors that may suffer a transient corruption due to a variety of mechanisms. Additionally, data corruption may occur as the result of hardware failures such as loose memory modules, blown chips, wiring defects, and/or the like. The errors caused by such failures are referred to as repeatable errors, since the same physical mechanism repeatedly causes the same pattern of data corruption.

To address this problem, a variety of error detection and error correction algorithms have been developed. In general, error detection algorithms typically employ redundant data added to a string of data. The redundant data is calculated utilizing a check-sum or cyclic redundancy check (CRC) operation. When the string of data and the original redundant data is retrieved, the redundant data is recalculated utilizing the retrieved data. If the recalculated redundant data does not match the original redundant data, data corruption in the retrieved data is detected.

Error correction code (ECC) algorithms operate in a manner similar to error detection algorithms. When data is stored, redundant data is calculated and stored in association with the data. When the data and the redundant data are subsequently retrieved, the redundant data is recalculated and compared to the retrieved redundant data. When an error is detected (e.g, the original and recalculated redundant data do not match), the original and recalculated redundant data may be used to correct certain categories of errors. An example of a known ECC scheme is described in “Single Byte Error Correcting-Double Byte Error Detecting Codes for Memory Systems” by Shigeo Kaneda and Eiji Fujiwara, published in IEEE TRANSACTIONS on COMPUTERS, Vol. C31, No. 7, July 1982.

In general, ECC algorithms may be embedded in a number of components in a computer system to correct data corruption. Frequently, ECC algorithms may be embedded in memory controllers such as coherent memory controllers in distributed shared memory architectures. The implementation of the ECC algorithm generally imposes limitations upon the implementation of a memory controller such as bus width and frequency. Accordingly, the implementation of the ECC algorithm may impose operational limitations on memory transactions.

### BRIEF SUMMARY OF THE INVENTION

In an embodiment, cache lines may be stored in memory by a memory controller. The memory controller formats cache lines into a plurality of portions for storage in the plurality of memory components, implements an error correction code (ECC) to correct a single-byte error in an ECC code word for pairs of the plurality of portions, stores even nibbles of respective pairs of the plurality of portions during respective first bus cycles, and stores odd nibbles of the respective pairs of plurality of portions during respective second bus cycles such that each byte of the respective pairs of the plurality of portions is stored in a single one of the plurality of memory components.

### BRIEF DESCRIPTION OF THE DRAWINGS

FIG. 1 depicts a memory controller system according to representative embodiments.

FIG. 2 depicts cache line format that may be utilized by a memory controller implemented according to representative embodiments.

FIG. 3 depicts a cache line layout that may be utilized to store cache data in memory by a memory controller implemented according to representative embodiments.

FIG. 4 depicts a flowchart for processing of cache data adapted to an ECC algorithm according to representative embodiments.

FIG. 5 depicts a memory system in which an ECC algorithm may selectively apply erasure mode error correction to data retrieved from limited portions of the memory system.

FIGS. 6 and 7 depict flowcharts for processing of cache data adapted to an ECC algorithm according to representative embodiments.

### DETAILED DESCRIPTION

Representative embodiments advantageously implement a byte error correction ECC algorithm within a memory system to provide increased reliability of the memory system. Specifically, representative embodiments may store cache lines in memory by distributing the various bits of the cache line across a plurality of DRAM components. When the byte ECC algorithm is combined with an appropriate distribution of data across the plurality of DRAM components, representative embodiments may tolerate the failure of an entire DRAM component without causing the failure of the entire memory system. Representative embodiments may also utilize a dual-cycle implementation of an ECC scheme to adapt the ECC scheme to optimize the utilization of an associated bus. Representative embodiments may selectively enable an “erasure” mode for the ECC algorithm when a repeatable error is identified to increase the probability of correcting additional errors. The erasure mode may be applied to a limited portion of the memory system to decrease the probability of incorrectly diagnosed data corruption.

Representative embodiments may utilize a suitable Reed-Solomon burst error correction code to perform byte correction. In Reed-Solomon algorithms, the code word consists of n m-bit numbers: C=(c, cₙ₋₂, . . . ,cₒ). The code word may be represented mathematically by the following polynomial of degree n with the coefficients (symbols) being elements in the finite Galios field (2^{m}): C(x)=(cxⁿ⁻¹+cₙ₋₂xⁿ⁻² . . . +cₒ). The code word is generated utilizing a generator polynomial (typically denoted by g(x)). Specifically, the payload data (denoted by u(x)) is multiplied by the generator polynomial, i.e., C(x)=x^{n-k}u(x)+[x^{n-k}u(x)mod(g(x))] for systematic coding. Systematic coding causes the original payload bits to appear explicitly in defined positions of the code word. The original payload bits are represented by x^{n-k}u(x) and the redundancy information is represented by [x^{n-k}u(x)mod(g(x))].

When the code word is subsequently retrieved from memory, the retrieved code word may suffer data corruption due to a transient failure and/or a repeatable failure. The retrieved code word is represented by the polynomial r(x). If r(x) includes data corruption, r(x) differs from C(x) by an error signal e(x). The redundancy information is recalculated from the retrieved code word. The original redundancy information as stored in memory and the newly calculated redundancy information are combined utilizing an exclusive-or (XOR) operation to form the syndrome polynomial s(x). The syndrome polynomial is also related to the error signal. Using this relationship, several algorithms may determine the error signal and thus correct the errors in the corrupted data represented by r(x). These techniques include error-locator polynomial determination, root finding for determining the positions of error(s), and error value determination for determining the correct bit-pattern of the error(s). For additional details related to recovery of the error signal e(x) from the syndrome s(x) according to Reed-Solomon burst error correction codes, the reader is referred to THE ART OF ERROR CORRECTING CODES by Robert H. Morelos-Zaragoza, pages 33-72 (2002), which is incorporated herein by reference.

Erasures in error correction codes are specific bits or specific strings of bits that are known to be corrupted without resorting to the ECC functionality. For example, specific bits may be identified as being corrupted due to a hardware failure such as a malfunctioning DRAM component, a wire defect, and/or the like. Introduction of erasures into the ECC algorithm is advantageous, because the positions of the erased bits are known. Let d represent the minimum distance of a code, v represent the number of errors, and μ represent the number of erasures contained in a received ECC code word. Then, the minimum Hamming distance between code words is reduced to at least d−μ in the non-erased portions. It follows that the error-correcting capability is [(d−μ−1)/2] and the following relation is maintained: d>2v+μ. Specifically, this inequality demonstrates that for a fixed minimum distance, it is twice as “easy” to correct an erasure as it is to correct a randomly positioned error.

In representative embodiments, the ECC algorithm of a memory controller may implement the decoding procedure of a [36, 33, 4] shortened narrow-sense Reed-Solomon code (where the code word length is 36 symbols, the payload length is 33 symbols, and the Hamming distance is 4 bits) over the finite Galios field (2⁸). The finite Galios field defines the symbol length to be 8 bits. By adapting the ECC algorithm in this manner, the ECC algorithm may operate in two distinct modes. In a first mode, the ECC algorithm may perform single-byte correction in which the term “single-byte” refers to 8 contiguous bits aligned to 8-bit boundaries. A single-byte error refers to any number of bits within a single-byte that are corrupted. Errors that cause bit corruption in more than one byte location are referred to as “multiple-byte errors” which are detected as being uncorrectable. In the second mode (the erasure mode), a byte location (or locations) is specified in the ECC code word as an erasure via a register setting. The location may be identified by a software or firmware process as a repeatable error caused by a hardware failure. Because the location of the error is known, in the erasure mode, the ECC algorithm can correct the byte error associated with the erasure and one other randomly located single-byte error (or two erasure single-byte errors if desired).

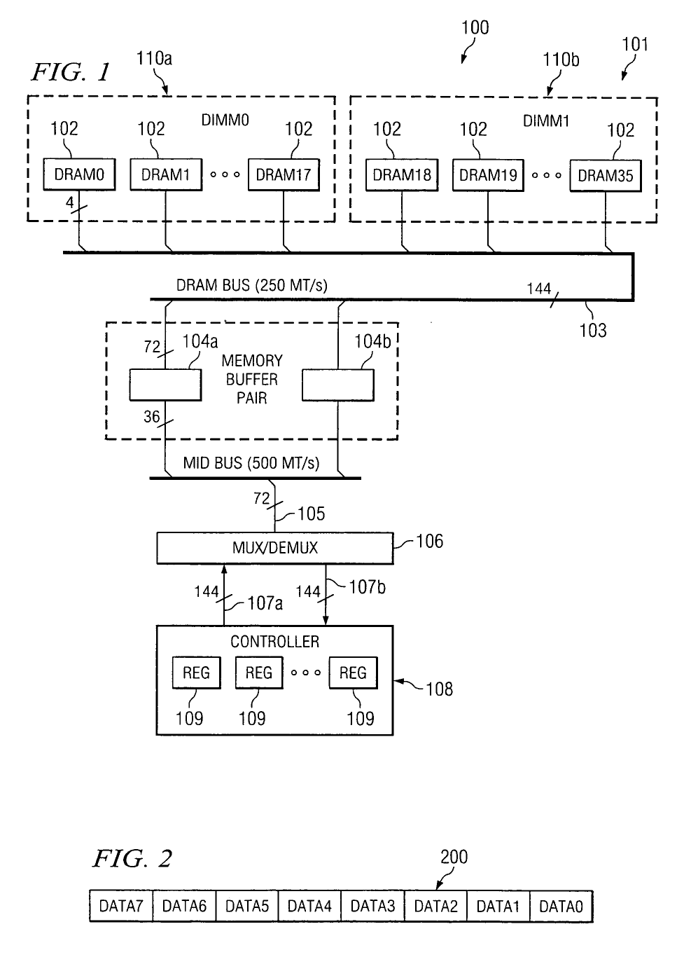

Referring now to the drawings, FIG. 1 depicts system 100 adapted to implement a suitable ECC code such as the [36, 33, 4] shortened narrow-sense Reed-Solomon code according to representative embodiments. System 100 comprises a plurality of dual in-line memory modules (DIMMs) shown as 110a and 110b. Additional DIMMs 110 (not shown) may be utilized if desired as will be discussed in greater detail below. Each of DIMMs 110a and 110b include a plurality of 4-bit wide DRAM components 102 (shown as DRAM0-DRAM 17 and DRAM18-DRAM35, respectively). Thus, DIMMs 110a and 110b form logical rank 101 that has a width of 144 bits. DIMMs 110a and 110b are communicatively coupled to a plurality of buffer chips 104a and 104b by bus 103 (or multiple buses). Buffer chips 104a and 104b operate in parallel to buffer cache lines and to translate between respective buses. Specifically, bus 103 may possess a width of 144 bits at 250 MT/s and bus 105 may possess a width of 72 bits and operate at 500 MT/s. Bus 105 may be demultiplexed by multiplexer/demultiplexer (MUX/DEMUX) 106. Controller 108 may communicate with demultiplexer 106 via two unidirectional 144-bit buses (one for incoming data and the other for outgoing data).

Controller 108 may process cache lines associated with data stored in DIMMs 110a and 110b according to representative embodiments. By suitably distributing data over the various DRAM components 102 and by utilizing a suitably adapted byte correction ECC algorithm, system 100 enables an entire DRAM component 102 to fail without causing the failure of memory system 100. The error correcting functionality of controller 108 may implement an ECC utilizing standard logic designs. Specifically, the ECC functionality of controller 108 may be implemented utilizing XOR trees, shift-registers, look-up tables, and/or other logical elements. Moreover, controller 108 may selectively enable erasure mode processing for data stored in DIMM 110a utilizing registers 109.

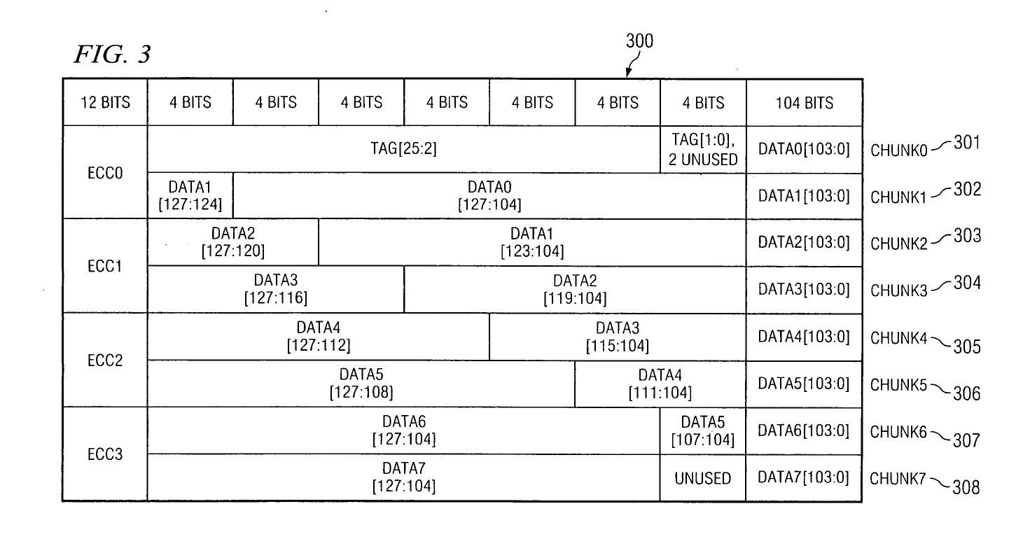

FIGS. 2 and 3 depict a cache line format and a cache line layout for implementation by controller 108 to facilitate the storage of cache data across a plurality of DRAM components 102 according to representative embodiments. Specifically, cache line format 200 in FIG. 2 depicts the cache line format for communication of cache data to and from processors (not shown in the drawings) in, for example, a distributed shared memory architecture. The respective bits (indexed from 0 to 1023) of the cache line are apportioned into a plurality of groups (denoted by DATA0-DATA7). Each of the groups contains 128 bits.

Cache line layout 300 in FIG. 3 illustrates how the respective bits of cache lines received from processors are stored in DRAM components 102 by controller 108 with ECC information and directory tag information. The ECC bits (the redundancy information) may be calculated utilizing the Reed-Solomon code algorithm. The directory tag information may be created and updated in accordance with a memory coherency scheme to enable system 100 to operate within a distributed shared memory architecture. Cache line layout 300 divides the cache line data, tag data, and ECC bits into eight portions (shown as 301-308) with each portion having 144 bits of data. Each portion includes 12 ECC bits. The ECC bits are used to correct errors in two respective portions. For example, the 12 ECC bits of portion 301 and the 12 ECC bits of portion 302 are used to correct byte errors in the ECC code word formed by both of portions 301 and 302. Furthermore, the 26 bits of tag data are stored in portion 301. The cache line data groups (DATA7-DATA0) are staggered though portions 301-309. As previously noted, DIMMs 110a and 110b form logical rank 101 that has a width of 144 bits. Cache line layout 300 is adapted according to the physical layout of DIMMs 110a and 110b. When cache line layout 300 is adapted in this manner, each of portions 301-308 may be stored across logical rank 101.

By distributing each of portions 301-308 over DRAM components 102 and by utilizing the discussed Reed-Solomon code, an entire DRAM component 102 may fail without causing the failure of memory system 100. Specifically, each respective two portions (e.g., portions 301 and 302) that share the 24 ECC bits may be stored across logical rank 101. The even nibbles (i.e., the first four bits of a single-byte) of the ECC code word may be stored across respective 36 DRAM components 102 of logical rank 101 during a first bus cycle. Then, the odd nibbles of the ECC code word may be stored across the 36 DRAM components 102 utilizing the same pattern as the even nibbles during a second bus cycle. Thereby, each single-byte (8 contiguous bits aligned to 8-bit boundaries) is stored with a single DRAM component 102. When one of the DRAM components 102 fails, the resulting data corruption of the particular ECC code word is confined to a single-byte. Thus, the ECC algorithm may correct the data corruption associated with the hardware failure and may also correct another error in another byte. Accordingly, the architecture of system 100 and the implementation of controller 108 may optimize the error correcting functionality of the ECC algorithm.

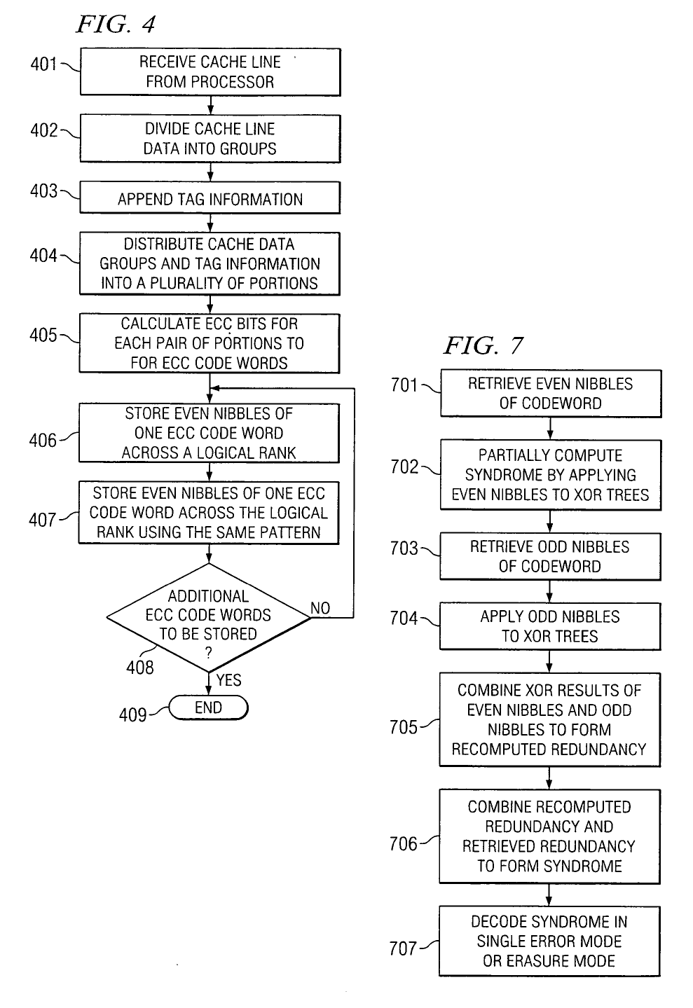

FIG. 4 depicts a flowchart for processing cache lines by controller 108 according to representative embodiments. In step 401, a cache line is received from a processor. In step 402, the cache line data is divided into groups. In step 403, tag information is appended to one of the groups. In step 404, the cache data groups and the tag information is distributed into a plurality of portions. In step 405, ECC bits are calculated for each pair of the portions to form ECC code words that consist of the ECC bits and the respective cache data and/or the tag information. In step 406, the even nibbles of one ECC code word are stored across a logical rank. In step 407, the odd nibbles of the ECC code word are stored across the logical rank using the same pattern. In step 408, a logical comparison is made to determine whether additional ECC code words remain to be stored. If additional ECC code words remain to be stored, the process flow returns to step 406. If not, the process flow proceeds to step 409 to end the process flow.

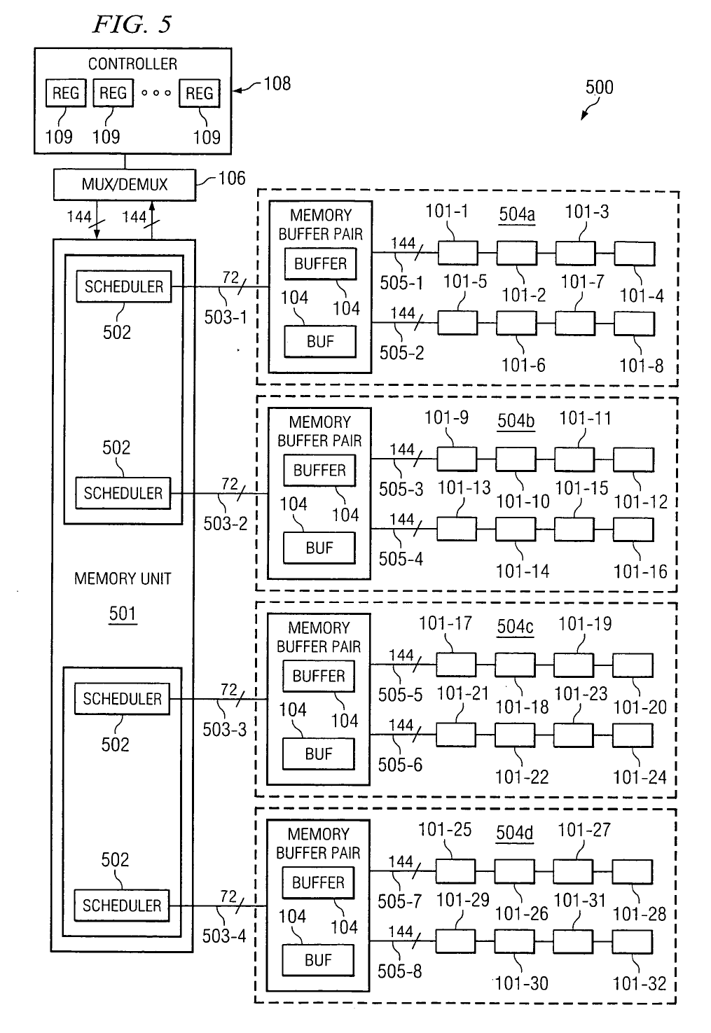

In representative embodiments, controller 108 may apply the erasure mode correction to various portions of a memory system such as memory system 500 of FIG. 5. Memory system 500 includes a plurality of memory quadrants 504a-504d for storage and retrieval of data through memory unit 501 by controller 108. Memory unit 501 includes a plurality of schedulers 502 to schedule access across quadrant buses 503. Quadrant buses 503-1 through 503-4 may be implemented utilizing a bus width of 72 bits. By utilizing a bus width of 72 bits and by suitably communicating an ECC code word in respective cycles, each single-byte of an ECC code word is transmitted across a respective pair of wires of a respective quadrant bus 503. If wire failures associated with one of quadrant buses 503 are confined to two or less single-bytes of an ECC code word, controller 108 may compensate for the wire failure(s) by utilizing the erasure mode and identification of the respective error pattern.

Furthermore, each of quadrants 504 include a pair of memory buffers 104. Each memory buffer 104 is coupled to a respective DRAM bus (shown as 505-1 through 505-8). Also, four logical memory ranks (shown as 101-1 through 101-32) are coupled to each DRAM bus 505. Each DRAM bus 505 has a bus width of 144 bits. By utilizing a bus width of 144 bits and by communicating data in respective bus cycles, each single-byte of an ECC code word is transferred across a respective set of four wires of DRAM bus 505. Thus, if any set of wire failures affects two or less single-bytes of an ECC code word, controller 108 may compensate for the wire failures by utilizing the erasure mode and identification of the respective error pattern.

Each memory rank 101 includes a plurality of DRAM components 102 within respective DIMMs 110 (see discussion of FIG. 1). Controller 108 may also compensate for failures of ones of DRAM components 102 as previously discussed.

Registers 109 may identify whether the erasure mode should be applied to data retrieved from a specific bank (subunit within a logical rank 101), logical rank 101 (pair of DIMMs 110 accessed in parallel), DRAM bus 505, quadrant bus 503, and/or any other suitable hardware component depending upon the architectural implementation. The capability to specify multiple independent erasures increases the probability that multiple repeatable failures in the memory system can be corrected. For example, two erasures may be specified, allowing two different repeatable errors associated with two different ranks or two different DRAM buses, etc. to be corrected.

Also, in erasure mode, a small percentage of uncorrectable errors may be decoded as correctable. The capability to specify the erasure for a limited region of the memory system reduces the probability of uncorrectable errors being misdiagnosed as correctable. For example, if a hardware error causes the corruption of a single-byte error for ECC code words communication via DRAM bus 505-1, one of registers 109 may be set to identify the specific byte of location of the ECC code word for that bus. When ECC code words are received from DRAM bus 505-1, the erasure mode may be applied to those ECC code words to address the data corruption. Moreover, the application of the erasure mode to those ECC code words may be independent of the processing of ECC code words retrieved from DRAM buses 505-2 through 505-8. Accordingly, the increased probability of misdiagnosed uncorrectable errors is limited to a specific subset of the memory system.

In the case where multiple erasures are identified, the portions of memory system 500 corresponding to each erasure should not overlap. That is, it is not advantageous to specify an erasure location associated with a specific rank and a different erasure location associated with the DRAM bus 505 containing that rank.

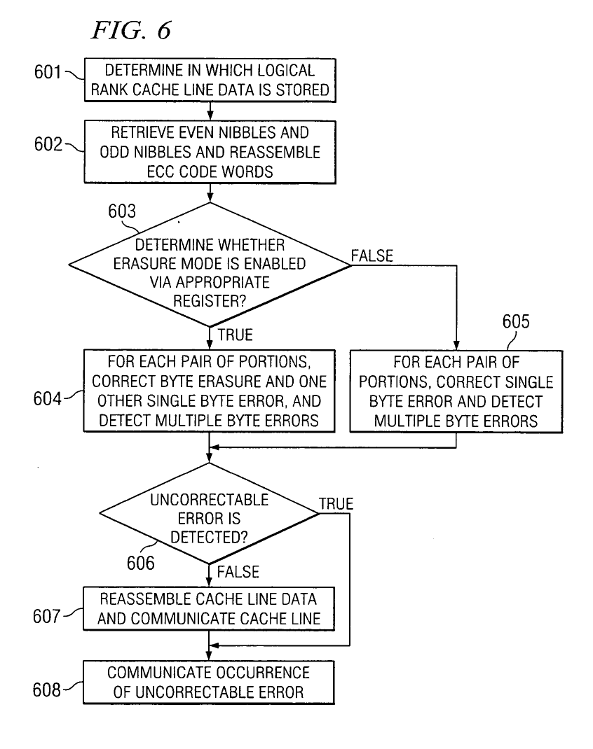

FIG. 6 depicts a flowchart for retrieving data stored in a memory system according to representative embodiments. In step 601, the logical rank in which cache line data is stored is determined. In step 602, the cache line is retrieved as a set of four consecutive ECC code words that enter the memory controller in eight consecutive cycles of data. Each ECC code word consists of two consecutive cycles with the even nibbles in the first cycle and the odd nibbles in the second cycle. In step 603, it is determined whether the erasure mode is enabled for the retrieved data via the value of the appropriate register(s). If the determination is true, the process flow proceeds to step 604. In step 604, for each respective pair of cache line data portions, the erasure byte due to the physical malfunction is corrected, one other byte error (if present) may be corrected, and multi-byte errors (if present) may be detected. If the logical determination of step 603 is false, the process flow proceeds to step 605. In step 605, for each respective pair of cache line data portions, a single byte error (if present) may be corrected and multi-byte errors (if present) may be detected. From both of steps 604 and 605, the process flow proceeds to step 606. In step 606, a logical comparison is made to determine whether an uncorrectable error (i.e., multi-byte errors) has been detected. If false, the process flow proceeds to step 607 where the cache line data is reassembled and the cache line is communicated to an appropriate processor. If the logical determination of step 606 is true, the process flow proceeds to step 608 where the occurrence of an uncorrectable error may be communicated using a suitable error signal.

Moreover, representative embodiments may also optimize the ECC algorithms for implementation in hardware according to the architecture of system 100. Specifically, commonly implemented ECC algorithms assume that all of the payload data is immediately available when the ECC bits are calculated. However, as previously discussed, representative embodiments retrieve the even nibbles of a code word in a first bus cycle and retrieve the odd nibbles of the code word in another bus cycle (see discussion of FIG. 6). Thus, in representative embodiments, there is some delay until all of the code word bits become available. Representative embodiments may advantageously begin processing the first group of nibbles immediately without waiting for the second group of nibbles.

FIG. 7 depicts a flowchart for processing retrieved data according to representative embodiment. In step 701, the even nibbles of a code word are retrieved. In step 702, the redundancy is partially computed by applying combinations of the retrieved bits to XOR trees. In step 703, the odd nibbles are retrieved. Step 703 may occur concurrently with the performance of step 702. When the odd nibbles are retrieved, the odd nibbles may be applied to XOR trees (step 704). In step 705, the results of the application of the even nibbles and the odd nibbles to XOR trees are combined by an XOR operation to form the full redundancy. While the recomputed redundancy is generated in this fashion, the retrieved redundancy may be assembled from its even and odd nibbles in the first and second cycles respectively. The recomputed redundancy and the retrieved redundancy are combined by an XOR operation to generate the syndrome (step 706). The syndrome is then decoded in one of two modes (step 707). If erasure mode has not been specified for the ECC code word, the syndrome is decoded to determine the location and value of a single-byte error. If erasure mode has been specified, a different decoding process is used to determine the value of the error in the erasure location and the location and value of an additional single-byte error, if one exists.

Representative embodiments may provide a number of advantageous characteristics. For example, by utilizing an ECC algorithm that corresponds to the physical implementation of system 100, the bus width may be maintained at a reasonable width. By maintaining the width of the bus in this manner, the bus utilization is increased thereby optimizing system performance. Moreover, by selectively applying an erasure mode for the ECC algorithm, the number of correctable errors due to hardware failures is increased and the probability of an uncorrectable multi-byte error being misdiagnosed is reduced. Furthermore, by ensuring each single-byte of an ECC code word is stored within a single DRAM component, representative embodiments enable an entire DRAM component to fail without causing the failure of the entire memory system. Likewise, wire failures in various buses that affect two or less single-bytes of ECC code words may be addressed to prevent failure of the memory system.

What is claimed is:

1. A memory controller system, comprising:
a plurality of memory components;
a bus for communicating data to and from said plurality of memory components; and
a memory controller for storing and retrieving cache lines through at least said bus, said memory controller being operable to format cache lines into a plurality of portions for storage in said plurality of memory components, said memory controller being further operable to implement an error correction code (ECC) to correct a single-byte error in an ECC code word for pairs of said plurality of portions, said memory controller being operable to store even nibbles of respective pairs of said plurality of portions during respective first bus cycles and to store odd nibbles of said respective pairs of plurality of portions during respective second bus cycles such that each single-byte of said respective pairs of said plurality of portions is stored in a single one of said plurality of memory components.

2. The memory controller system of claim 1 wherein said bus has a bus width and said ECC code word has a code word length that is greater than said bus width.

3. The memory controller system of claim 2 wherein said code word length is twice as long as said bus width.

4. The memory controller system of claim 3 wherein said bus width is 144 bits and said code word length is 288 bits.

5. The memory controller system of claim 1 wherein each of said memory components has a bit-width of four bits.

6. The memory controller system of claim 1 wherein said plurality of memory components includes a plurality of dual in-line memory modules (DIMMs) that form a logical rank that has a bit-width equal to one-half of a length of said ECC code word.

7. The memory controller system of claim 6 wherein said memory controller stores pairs of said plurality of portions across said logical rank.

8. The memory controller system of claim 1 wherein said memory controller is further operable to correct an erasure byte in a second mode of ECC operation.

9. The memory controller system of claim 1 wherein said memory controller is operable to calculate an ECC syndrome, wherein said calculation of said syndrome includes applying combinations of retrieved first nibbles of an ECC code word to a set of XOR trees before second nibbles of said ECC code word are retrieved.

10. The memory controller system of claim 1 wherein said memory components are DRAM memory components.

11. A method for processing cache lines, comprising:
receiving cache line data;
dividing said cache line data into a plurality of portions;
calculating an error correction code (ECC) code word for pairs of said plurality of portions, wherein said ECC code words include sufficient redundant information to enable recovery of single-byte errors;
storing respective even nibbles of said ECC code words into a plurality of memory components during respective first bus cycles; and
storing respective odd nibbles of said ECC code words into said plurality of memory components during respective second bus cycles such that each byte of said respective pairs of said plurality of portion is stored in a single one of said plurality of memory components.

12. The method of claim 11 wherein said storing respective even nibbles and storing respective odd nibbles occurs over a bus that has a bus width and wherein said ECC code words have a code word length that is twice the bus width.

13. The method of claim 11 wherein each of said memory components has a bit-width of four bits.

14. The method of claim 13 further comprising:
retrieving said ECC code words from said plurality of memory components;
correcting an erasure error in said ECC code words when a register value is set to identify a byte location of said erasure error; and
correcting a single-byte error in said ECC code words.

15. The method of claim 14 further comprising:
retrieving a second set of ECC code words from a second plurality of memory components; and
correcting a single-byte error in said ECC code words when a register value is set to a value that indicates that an erasure error is not present.

16. The method of claim 11 wherein said plurality of memory components form a logical rank that has a bit-width that is equal to a code word length of said ECC code words.

17. The method of claim 11 further comprising:
retrieving a first set of nibbles of an ECC code word from said plurality of memory components;
retrieving a second set of nibbles of an ECC code word from said plurality of memory components; and
calculating an ECC syndrome, wherein said calculating includes applying said combinations of said first set of nibbles to a set of XOR trees before said second set of nibbles are retrieved.

18. A memory controller system, comprising:
a plurality of memory buffers that are each coupled to a respective DRAM bus, wherein a plurality of DRAM components are accessible on each respective DRAM bus;
a plurality of buses that are each coupled to a respective memory buffer of said plurality of memory buffers; and
a memory controller for storing and retrieving cache line data through at least said plurality of buses, said memory controller being further operable to correct a single byte error in a first mode and at least one erasure byte error in a second mode according to an error correction code (ECC) algorithm for ECC code words that include cache line data, wherein said memory controller includes a first plurality of registers to identify erasure bytes caused by malfunctioning ones of said plurality of DRAM components, a second plurality of registers to identify erasure bytes caused by malfunctioning ones of said plurality of buses, and a third plurality of registers to identify erasure bytes causes by ones of said DRAM buses.

19. The memory controller system of claim 18 wherein said memory controller is operable to store even nibbles of an ECC code word during a first bus cycle and to store odd nibbles of said ECC code word during a second bus cycle.

20. The memory controller system of claim 19 wherein said ECC code words have a length that is greater than a width of logical ranks of defined by respective ones of said plurality of memory components, wherein said memory controller stores each ECC code word in a respective logical rank such that each single byte of a respective ECC code word is stored in a single DRAM component of said respective logical rank.
